(19) United States
(12) Patent Application Publication
(10) Pub. No.: US 2006/0008034 A1
(43) Pub. Date: Jan. 12, 2006

(54) Spreading codes for quasisynchronous code division multiple access systems

(76) Inventors: Glyn Wyman, Bristol (GB); Richard Anthony Jones, Bristol (GB); Derek Howard Smith, Mid-Glamorgan (GB); Stephanie Perkins, Mid-Glamorgan (GB); Geoffrey Raymond Bradbeer, Malvern (GB)

Correspondence Address: CROWELL & MORING LLP;INTELLECTUAL PROPERTY GROUP, P.O. BOX 14300, WASHINGTON, DC, 20044-4300, US

(21) Appl. No.: 10/493,421

(22) PCT Filed: Dec. 18, 2003
(86) PCT No.: PCT/GB03/05512

§ 371 Date: Aug. 10, 2005

(30) Foreign Application Priority Data
Dec. 23, 2002 (DE) 0230260.2

(51) Int. Cl. H03D 1/00

(52) U.S. Cl. 375/343

(57) ABSTRACT

Described herein is a method of generating spreading codes which ensures that the cross-correlation is −1 for all pairs of sequences within the relevant time delays.

The present invention relates to improvements in or relating to spreading codes for quasisynchronous code division multiple access systems, and is more particularly concerned with the optimisation of code assignment for such systems.

It is well known to use asynchronous code division multiple access (CDMA) systems in communications systems and to make use of spreading codes which have correlation properties close to the best possible achievable properties. However, the demand for high traffic levels in modern communications systems imposes ever more stringent requirements on such systems, for example, the minimisation of multi-user interference. At the same time, the so-called quasisynchronous CDMA (QS-CDMA) systems are becoming more practical.

In QS-CDMA systems, the chips of the information symbols of the users should be nearly synchronised, normally to within a small number of chips, referred to as the synchronisation uncertainty τₘₐₓ. This “synchronisation” can be achieved, for example, by providing each user of the system with a global positioning system (GPS) receiver and triggering the user bit epochs by a GPS clock. The relative delays of received signals can then be held to within a few chips.

Among the candidate spreading codes are m-length sequences, the small Kasami set, the Gold codes and the large Kasami set. These terms are well known in the relevant technical field and no further discussion will be given here. These codes correspond to periodic binary sequences.

When the CDMA system is completely asynchronous, a separate, cyclically distinct periodic sequence is assigned to each user and it is possible to assign many users to different phases of the same sequence provided that the phases are separated by at least 2τₘₐₓ+1 cyclic shifts and a suitable synchronisation mechanism is provided. If T is the left cyclic shift operator on code vectors, u is a periodic sequence of period p, then there are exactly p sequences (or binary code vectors) u,T(u),T²(u), . . . ,T^{p-1}(u). These sequences are cyclic shifts of u and are known as the different phases of u. However, large sets of m-length sequences with good correlation properties do no exist.

Moreover, as the spectrum is a fixed asset which is continuously subject to requests which increases its packing density, it is necessary to find a solution which overcomes these problems. One solution is to utilise higher frequencies but this is not practical as constraints are imposed by the propagation of the higher frequencies. Furthermore, there is a requirement for compatibility to be maintained using existing carriers in some systems.

It is therefore an object of the present invention to provide an improved quasisynchronous code division multiple access system which overcomes the problems mentioned above.

In accordance with one aspect of the present invention, there is provided a method of generating codes for a multiplicity of cliques in which the properties within the cliques are orthogonal or pseudo orthogonal and the cross-correlation of pairs selected from different cliques exhibit pseudo orthogonal properties within specific time windows.

By the term ‘clique’ is meant a fully connected subset of constraints as will be readily understood by a person of ordinary skill in the art.

The pairs may be selected from different cliques are such that both elements of each pair are in the small Kasami set.

Alternatively, the pairs selected from different cliques are such that one element of each pair is in the small Kasami set and the other element of each pair is a Gold code.

As a further alternative, the pairs selected from different cliques are such that each element of each pair is generated by a simplex code.

In one embodiment of the present invention, it has been noted that the small Kasami set has good cross-correlation properties and it is possible to use several different phases of the same sequence for different users. Moreover, the small Kasami set contains an m-length sequence, and is embedded within the large Kasami set which also contains a set of Gold codes. Whilst it may be thought that the small Kasami set is too small to be useful in a system with many users, this assumption ignores the following:
1. The possibility of re-using codes for transmitters with no potential for interference.
2. The possibility of assigning as

$$\vert \frac{p}{( 2 {τ}_{max} + 1 )} \vert$$

phases of the same sequence to different users.
3. The possibility of assigning the small Kasami set so that the best correlation properties belong to the more critically important pairs of transmitters with respect to multiple access interference. Indeed, the small Kasami set contains an m-length sequence and some of the most important pairs of transmitters can be assigned different phases of this sequence. Should the small Kasami set prove inadequate, some transmitters can be assigned Gold codes, and the correlation of a small Kasami code-Gold code pair is no worse than that of a Gold code pair. Such an assignment is made to a pair where the interference potential is relatively limited.

It is therefore proposed that careful assignment of code pairs in a quasisynchronous code division multiple access (QS-CDMA) system can be utilised to maximise both re-use of the code pairs and take advantage of the benefits of the small Kasami set whilst, at the same time, ensuring that the number of available user codes is adequate.

An essential features for the codes used in accordance with the present invention is that the codes must have certain correlation properties. In this way, given a (0,1) binary vector, it is usual in correlation calculations to consider it as a (+1,−1) vector, using the mapping 0→(+1), 1→(−1). Let x={x₀,x₁, . . . ,xₚ₋₁}, y={y₀,y₁, . . . , yₚ₋₁} be vectors with entries +1,−1, then the autocorrelation function on x is defined by:

$${θ}_{x} ( τ ) = {\sum }_{i = 0}^{p - 1} {x}_{i} {x}_{i + τ} mod p .$$

Clearly if τ≡0 mod p then θₓ(τ)=p. If τ≠0 mod p then θₓ(τ) is generally required to be small. In quasisynchronous systems, it may be simply required that, for any user code x, then θₓ(τ) is small for 0<|τ|≦τₘₐₓ.

In a similar way, the cross-correlation function on x,y is defined to be

$${θ}_{x , y} ( τ ) = {\sum }_{i = 0}^{p - 1} {x}_{i} {y}_{i + τ} mod p$$

where θ_{x,y}(τ) is generally required to be small for all τ. In quasisynchronous systems, it may be simply required that, for any user codes x and y, then θ_{x,y}(τ) is small for 0<|τ|≦τₘₐₓ.

The correlation functions can also be defined in the same way when the periods of the sequences are divisors of p. The correlation functions can also be defined over windows of length w<p. In this case the definitions are:

$${θ}_{x} ( τ , k ) = {\sum }_{i = 0}^{w - 1} {x}_{i + k} {x}_{i + k + τ} mod p$$

$$and$$

$${θ}_{x , y} ( τ , k ) = {\sum }_{i = 0}^{w - 1} {x}_{i + k} {y}_{i + k + τ} mod p$$

If we define c₁=max_{x≠y} max_{0≦τ≦p-1}|θ_{x,y}(τ)|, c₂=maxₓ max_{1≦τ≦p-1}|θₓ(τ)| and cₘₐₓ=max(c₁,c₂). Then, according to the disclosure by L. R. Welch in “Lower bounds on the maximum cross correlation of signals”, IEEE Trans. Inform. Theory, Vol. IT-20, No. 3, pages 397 to 399, May 1974, asymptotically cₘₐₓ≧\sqrt{p} (and indeed the result is accurate even when the number of sequences is fairly small). This is subsequently referred to as the ‘Welch bound’.

In a similar way, over a window of length w, the lower bound is \sqrt{w}. Ideally, very small values of

$$\frac{\sqrt{p}}{p}$$

are required. The problem may be particularly difficult for small p or small w. It should be noted that these bounds do not apply in the quasisynchronous case.

Codes in the small Kasami set provide the requisite correlation properties. For the small Kasami set, let m be an even integer and let u denote an m-sequence of period N=2^{m}−1, generated by a primitive binary polynomial h(x) of degree m. If we define s(m)=2^{m/2}+1 and consider the sequence w obtained by taking every s(m)′^{th} bit of u. The sequence w is of period s(m)=2^{m/2}+1 and is generated by the polynomial h′(x) of degree m/2 whose roots are the s(m)′^{th} powers of the roots of h(x). This is discussed by D. V.

Sarwate and M. B. Pursley in “Crosscorrelation properties of pseudorandom sequences”, Proc. IEEE, Vol. 68, No. 5, pages 593 to 619, 1980.

Now consider the sequences generated by the polynomial h(x)h′(x) of degree 3m/2. Any sequence of period 2^{m}−1 generated is a sequence of the small Kasami set:
Kₛ(u)={u,u ⊕ w,u ⊕ Tw,u ⊕ T²w . . . ,y ⊕ T²^{^{m/2}}⁻²w},
where ⊕ denotes mod2 addition of the corresponding vectors.

Further, for the code vectors corresponding to the phases of these sequences, cₘₐₓ=s(m)=2^{m/2}+1. Thus, in the case of m being even, a set of 2^{m/2} sequences which meet the ‘Welch bound’ asymptotically is known. This proposal offers a method to use a small set in a system with a large number of users.

The small Kasami set is contained within the large Kasami set, which also includes Gold codes. These Gold codes can be expressed as:
G(u,v)={u,v,u ⊕ v,u ⊕ v,u ⊕ T²v . . . ,u ⊕ T²^{^{m/2}}⁻²v}
cₘₐₓ=s(m)
where u,v are m-sequences generated by a preferred pair of primitive polynomials as described in the disclosure by D. V. Sarwate and M. B. Pursley referenced above. In this large Kasami set,

$${c}_{max} = t ( m ) = 1 + {2}^{⌊ \frac{m + 2}{2} ⌋} .$$

cₘₐₓ=s(m) only holds if the code vectors are chosen as phases of sequences from the small Kasami set. Similarly, the small Kasami set contains the m-sequence u, and if the code vectors are chosen to be phases of this sequence, then cₘₐₓ=1.

The assignment of spreading codes in CDMA systems appears to have received almost no attention. There appear to be two basic reasons for this. The first reason is concerned with the need for code re-use. In many circumstances, particularly with long spreading codes, the number of codes available may be sufficiently large that code assignment is not a critical problem. An example of this is the long (scrambling) codes proposed for cells in UMTS mobile telephone systems. Code re-use is clearly more critical when the small Kasami set is used. The second reason is concerned with the assignment of codes so that constraints on the codes assigned to pairs of transmitters are satisfied. This does not generally arise when codes are used for which the maximum correlation between all pairs of codes is the same. This does not hold for the codes described here.

The algorithms described by R. K. Taplin, D. H. Smith and S. Hurley in “Frequency assignment with complex cosite constraints”, IEEE Trans. On Electromagnetic Compatibility, Vol. 43, No. 2, pages2lo to 218, 2001 can be modified for spreading code assignment. If f(tᵢ) denote the code assigned to a transmitter tᵢ. Pairs of transmitters t₁, t₂ have one of the following:
1. No constraint, in which case they can be assigned the same code;
2. A constraint |θ_{f(t}_{₁}_{),f(t}_{₂}₎(τ)|≦1 (0≦τ<τₘₐₓ), in which case both t₁ and t₂ must be assigned codes which are different phases (separated by at least 2τₘₐₓ+1 cyclic shifts) of the m-length sequence within the small Kasami set;
3. A constraint |θ_{f(t}_{₁}_{),f(t}_{₂}₎(τ)|≦s(m) (0≦τ≦τₘₐₓ), in which case both t₁ and t₂ must be assigned codes which are different phases (separated by at least 2τₘₐₓ+1 cyclic shifts) of sequences within the small Kasami set;
4. A constraint |θ_{f(t}_{₁}_{),f(t}_{₂}₎(τ)|≦t(m) (0≦τ≦τₘₐₓ), in which case both t₁ and t₂ must be assigned codes which are different phases (separated by at least 2τₘₐₓ+1 cyclic shifts) of sequences within the large Kasami set.

One way to derive these constraints might be to carry out signal-to-interference (SIR) calculations for the unspread signals in the same way as is done for frequency division multiple access (FDMA) systems. Three different thresholds γ₁≧γ₂≧γ₃ could be set for a “satisfactory” SIR. Then at a worst case receiver the appropriate constraint is set as follows:

1. If SIR≧γ₁ no constraint is necessary;

2. If γ₁>SIR≧γ₂ constraint 4) above is used;

3. If γ₂>SIR≧γ₃ constraint 3) above is used;

4. If γ₃>SIR constraint 2) above is used.

Care must be taken in the choice of the thresholds to ensure that there are not too many of the stronger constraints for the number of codes available. The frequency domains (or sets of available frequencies) in the frequency assignment algorithms are replaced by codewords which are equally spaced phases (separated by at least 2τₘₐₓ+1 cyclic shifts) of the various sequences. The cost function is simply a (weighted) sum of the number of constraint violations. Although it is not possible to give a theoretical estimate of the reduction of the multiple access interference in the system without making many assumptions, the assignment of the best code pairs to the most critical interfering pairs should ensure that the overall reduction is substantial.

In another embodiment of the present invention, a construction for spreading sequences based on simplex codes is proposed in which Θ_{X,Y}(0)=−1 is guaranteed. X. D. Lin and K. H. Chang have proposed a construction for spreading sequences for QS-CDMA (“Optimal PN sequence design for quasisynchronous CDMA communication systems”, IEEE Trans. Communications, Vol. 45, No. 2, pages 221 to 226, February 1997) in which the cross-correlation has a construction with Θ_{X,Y}(τ)=−1 for all values in the range except possibly τ=0.

Lin and Chang referenced above modified the construction of the GMW-sequences proposed by R. A. Scholtz and L. R. Welch in “GMW sequences”, IEEE Trans. Information Theory, Vol. IT-30, No.3, pages 549 to 553, May 1984 to create a family of

$$\frac{( \begin{matrix}{2}^{m} - 1 \\ {2}^{( m - 1 )}\end{matrix} )}{( {2}^{m} - 1 )}$$

cyclically distinct sequences of length N=2ⁿ−1 with

$${Θ}_{X , Y} ( τ ) = \{ \begin{matrix}- 1 & for τ \neq ( 0 mod T ) \\ {2}^{n - m} - 1 + {2}^{n - m} {θ}_{uv ( d )} & for τ = ⅆ T\end{matrix}$$

where Θᵤᵥ(d) is the cross-correlation function of certain seed sequences u, v. In Lin and Chang's examples Θ_{X,Y}=−1 for the chosen pair of vectors X,Y, but it is easy to see that if m>3, this cannot be the case for every pair.

Let cₘₐₓ=max_{τ}|Θ_{X,Y}(τ)| where 0≦|τ<T=2τₘₐₓ+1. Then as noted by X. H. Tang, P. Z. Fang and S. Matsufuji in “Lower bounds on correlation of spreading sequence set with low or zero correlation zone”, Electronic Letters, Vol. 36, No. 6, pages 210 to 218, March 2000, a modified ‘Welch bound’ for cₘₐₓ is:

$${c}_{max} \geq \sqrt{\frac{N ( u ( 2 {τ}_{max} + 1 ) - N )}{( u ( 2 {τ}_{max} + 1 ) - 1 )}} \qquad ( 1 )$$

This can be found by applying the inner product theorem discussed by Welch in “Lower bounds on the maximum cross correlation of signals” referenced above, to the set of vectors
{S_{-τ}_{ₘₐₓ}(cᵢ), S_{-τ}_{ₘₐₓ}₊₁(cᵢ), . . . , cᵢ, . . . , S_{τ}_{ₘₐₓ}₋₁(cᵢ), S_{τ}_{ₘₐₓ}(cᵢ)}
(mapped to vectors with elements from {−1,+1} and adjusted for norm N).

Thus, for the parameters considered by Lin and Chang, cₘₐₓ will significantly exceed 1 if u exceeds 2^{m}−1 where m>3. By restricting the choice of seed sequences in Lin and Chang's construction to a set of 2⁻1 cyclically distinct seed sequences with θ_{u,v}(0)=−1 to ensure that exactly 2−1 cyclically distinct sequences are obtained with Θ_{X,Y}(τ)=−1 for 0≦|τ|<T=2τₘₐₓ+1 and Θ_{X,X}(τ)=−1 for 0<|τ|<T=2τₘₐₓ+1.

Thus for sequences of odd length, the best cross-correlation possible is achieved, and according to inequality (1) above, the number of sequences is maximised for the given value of τₘₐₓ, and the value of τₘₐₓ is maximised for the given number of sequences.

Let α be a primitive element of the Galois field, GF(2ⁿ), and

$${Tr}_{m}^{n} ( x ) = {\sum }_{j = 0}^{n / m - 1} {x}^{{2}^{mj}}$$

be the trace function from GF(2ⁿ) to GF(2^{m}), then the properties of the trace function are as described in MacWilliams and Sloane referenced above.

The trace function is used to define a shift sequence S=(s₀, s₁, . . . , s₂_{ⁿ}₋₂) . Specifically, for k=0, 1, 2, . . . , 2ⁿ−2, if sₖ is defined by

$${s}_{k} = \{ \begin{matrix}i & if {Tr}_{m}^{n} ( {α}^{k} ) = {α}^{Ti} \\ ∞ & if {Tr}_{m}^{n} ( {α}^{k} ) = 0\end{matrix} \\ i ∈ \{ 0 , 1 , … , {2}^{′′′} - 2$$

The sequence X_{c} of length 2ⁿ−1 for a balanced seed vector, that is, with 2^{m-1} 1's and e=(e₀, e₁, . . . , e₂_{^{m}}₋₂), can be constructed from a (2^{m}−1)×T array with columns labelled 0, 1, . . . , T−1 as follows:

If sᵢ=∝, then the ith column is a column of zeros. If sᵢ≠∝, then the ith column is the transpose of (eₛ_{_{i, e}}ₛ_{₁}₊₁, . . . , eₛ₊₂_{^{m}}_{-2 mod(2}_{^{m}}₋₁₎) and thus is a cyclic shift of e. The array is shown below with the convention e_{∝}=0:

$$[ \begin{matrix}{e}_{{s}_{0}} & {e}_{{s}_{1}} & ⋯ & {e}_{{s}_{T - 1}} \\ {e}_{{s}_{0} + 1} & {e}_{{s}_{1} + 1} & ⋯ & {e}_{{s}_{T - 1} + 1} \\ ⋮ & ⋮ & ⋯ & ⋮ \\ {e}_{{s}_{0} + {2}^{′′′} - 2 mod ( {2}^{′′′} - 1 )} & {e}_{{s}_{1} + {2}^{′′′} - 2 mod ( {2}^{′′′} - 1 )} & ⋯ & {e}_{{s}_{T - 1} + {2}^{′′′} - 2 mod ( {2}^{′′′} - 1 )}\end{matrix} ]$$

Then Xₑ is obtained by scanning the rows of the array, starting in the top left hand corner to provide
Xₑ=(eₛ_{₀}, eₛ_{₁}, . . . , eₛ_{ᵣ₋₁}, eₛ_{_{T}}, . . . , eₛ_{_{2(T-1)}}, eₛ_{_{2T}}, . . . , eₛ_{₂}_{ⁿ}_{₋₂})

In a similar way, for a second balanced seed vector f, the sequence below can be constructed:
X_{f}=(fₛ_{₀}, fₛ_{₁}, . . . , fₛ_{_{T-1}}, fₛ_{_{T}}, . . . , fₛ_{_{2(T-1)}}, fₛ_{_{2T}}, . . . , fₛ_{₂}_{ⁿ}_{₋₂})

If the seed vectors are restricted to be codewords of a simplex code, then Θ_{X}_{ₑ}_{, X}_{_{f}} (0)=−1 for any pair Xₑ, X_{f} of sequences. Clearly, it is necessary for θ_{ef}(0)=−1 for any pair of seed vectors. It is also required that all the vectors must be cyclically distinct.

A simplex code is the dual of a Hamming code as discussed by F. J. MacWilliams and N. J. A. Sloane in “The theory of error-correcting codes”, Amsterdam, Elsevier 1996, 9^{th} Edition. It is a linear code with a generator matrix with columns formed from the set of all distinct, non-zero (0, 1) vectors of length m in some order. The code has parameters (2^{m}−1, m, 2^{(m-1)}). Thus a simplex code is an equidistant code and all 2^{m}−1 non-zero codewords have weight 2^{m-1}. It follows that if these 2^{m}−1 non-zero codewords are used as seed vectors, then θ_{ef}(0)=−1 for any pair. However, there is no guarantee that the code vectors are cyclically distinct. In fact, m-length sequences are simplex codes with a single cycle of non-zero codewords.

Cyclically distinct seed sequences e are necessary if the sequences Xₑ are to be cyclically distinct. Clearly, if S_{γ}(e)=e, then S_{γT}(Xₑ)=Xₑ. On the other hand, if S_{γT}(Xₑ)=Xₑ, it will follow that S_{γ}(e)=e by considering the positions congruent to 0modT. It is not possible that S_{τ}(Xₑ)=Xₑ with τ≠γT as the cross-correlation of the two sequences is −1.

Given a simplex code, it is possible to find an equivalent simplex code that has the maximum number of cyclically distinct codewords by using a hillclimbing algorithm or a metaheuristic which finds the equivalent simplex code in a very small number of iterations. An equivalent simplex code is a code with the columns of the generator matrix permuted. If m=3, there are at most 5 balanced vectors of length 7. Thus the algorithm cannot find 7 cyclically distinct codewords in an equivalent simplex code, but does find 5 very quickly. In the cases where m=4, 5, 6, 7, 8, the maximum number 2^{m}−1 of cyclically distinct code vectors in an equivalent code are found in a very small number of iterations.

The periodic odd correlation properties of a QS-CDMA system are as important as the even correlation properties as discussed by D. V. Sarwate and M. B. Pursley in “Crosscorrelation properties of pseudorandom sequences”, Proc. IEEE, Vol. 68, No. 5, pages 593 to 619, May 1980. Lin and Chang point out that the absolute value of the periodic odd correlation function |Θ_{XY}⁽⁰⁾(τ)| is bounded according to the inequality:
|Θ_{XY}⁽⁰⁾(τ)|≦|Θ_{XY}(τ)|+2|τ|

The same result holds for the more restricted class of sequences described above and shows that the odd correlation is small for small τ. However, the bound on the odd correlation is correspondingly smaller when τ=0.

Although the invention has been described with reference to binary vectors, it will readily be appreciated that the invention can also be applied to polyphase or multi-dimensional vectors.

Moreover, although the invention has been described with reference to QS-CDMA systems, it has wider applicability.

1. A method of generating codes for a multiplicity of cliques in which the properties within the cliques are orthogonal or pseudo orthogonal and the cross-correlation of pairs selected from different cliques exhibit pseudo orthogonal properties within specific time windows.

2. A method according to claim 1, wherein the pairs selected from different cliques are such that both elements of each pair are in the small Kasami set.

3. A method according to claim 1, wherein the pairs selected from different cliques are such that one element of each pair is in the small Kasami set and the other element of each pair is a Gold code.

4. A method according to claim 1, wherein the pairs selected from different cliques are such that each element of each pair is generated by a simplex code.

5. (canceled)
